(19) United States
(12) Patent Application Publication
(10) Pub. No.: US 2026/0288006 A1
(43) Pub. Date: Sep. 24, 2026

(54) POLYSILOXANE MATERIAL AND POLYSILOXANE COMPOSITION COMPRISING THE SAME

(71) Applicant: Merck Patent GmbH, Darmstadt (DE)

(72) Inventors: Sara Tanimoto, Shizuoka (JP); Takashi Fuke, Shizuoka (JP); Daishi Yokoyama, Shizuoka (JP); Atsuko Noya, Shizuoka (JP)

(21) Appl. No.: 19/477,176

(22) PCT Filed: May 15, 2024
(86) PCT No.: PCT/EP2024/063328

§ 371 Date: Oct. 21, 2025

(30) Foreign Application Priority Data
May 17, 2023 (JP) 2023-081686

(51) Int. Cl. G03F 7/075; C08G 77/00; C08G 77/50

(52) U.S. Cl. CPC G03F 7/0757; C08G 77/50; C08G 77/80

(57) ABSTRACT

[Problem] To provide a polysiloxane material good in bending performance. [Means for Solution] A polysiloxane having a certain structure, which is a polysiloxane (Pab) comprising a repeating unit represented by the formula (ia) and a repeating unit represented by the formula (ib), or a mixture of a polysiloxane (Pa) comprising the repeating unit represented by the formula (ia) and a polysiloxane (Pb) comprising the repeating unit represented by the formula (ib).

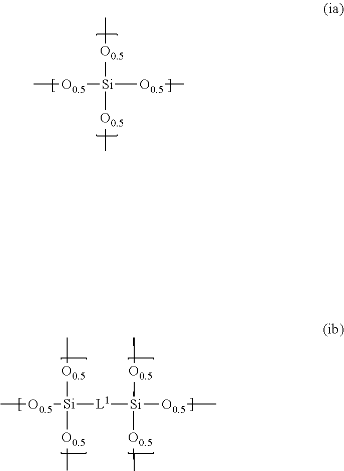

### BACKGROUND OF THE INVENTION

### Technical Field

The present invention relates to a polysiloxane material. The present invention relates to a polysiloxane composition comprising the same.

### Background Art

With the development of mobile devices such as smartphones, tablet PCs and small displays, making film thinner, making slimmer and making lighter are required, plastic resin has been studied, and it is incorporated in display devices such as mobile devices as an alternative material to glass.

Polysiloxane is known as a material for forming a cured film. In order to achieve a desired taper angle of the formed pattern, a photosensitive polysiloxane composition comprising a polysiloxane containing a certain repeating unit has been proposed (for example, Patent Document 1). In order to form a protective film having chemical resistance, a photosensitive polysiloxane composition containing a polysiloxane containing a certain repeating unit has been proposed (for example, Patent Document 2).

### PRIOR ART DOCUMENTS

### Patent Documents

[Patent document 1] WO 2019/129802
[Patent document 2] US 2015/0323868 A1

### SUMMARY OF THE INVENTION

### Problems to be Solved by the Invention

Since displays parts of which are bent or flexibly bent for aesthetic and functional reasons have recently received attention and this trend is becoming more prominent in mobile devices, the present inventors have focused on the fact that bending performance is required for cured films mounted in OLED displays and the like which are built into such devices.

Therefore, the present inventors considered that there are one or more problems regarding polysiloxane materials that still require improvement. Examples of these include the following: the bending performance of the cured film is insufficient; the sensitivity is low; the resolution of the formed pattern is low; the heat resistance of the cured film is low; scum on the cured film cannot be suppressed; the flatness of the cured film is low; the process window is narrow; and the manufacturing yield is low.

### Means for Solving the Problems

The polysiloxane material (I) according to the present invention is
a polysiloxane (Pab) comprising a repeating unit represented by the formula (ia) and a repeating unit represented by the formula (ib), or
a mixture of a polysiloxane (Pa) comprising the repeating unit represented by the formula (ia) and a polysiloxane (Pb) comprising the repeating unit represented by the formula (ib):

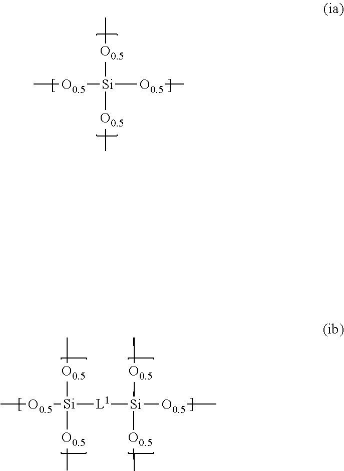

where
L¹ is C₄₋₁₂ linear alkylene;
one or more H in L¹ can be replaced with C₁₋₁₀ linear alkyl, C₃₋₁₀ branched alkyl, C₃₋₁₅ alkyl containing an alicyclic ring, C₆₋₁₅ aryl, —COOH or —OH; one or more non-adjacent methylene (—CH₂—) in L¹ can be replaced with -Ph-, —O—, —S—, —CO—, —CO—O—, —O—CO—, —O—CO—O—, —CR¹═CR²— or —C≡C—; and R¹ and R² are each independently H or C₁₋₆ linear alkyl.

The polysiloxane composition according to the present invention comprises the above-described polysiloxane material (I) and a solvent (II).

The method for manufacturing a film according to the present invention comprises applying the above-described composition above a substrate, optionally exposing, and developing.

The method for manufacturing a cured film according to the present invention comprises the above-described manufacturing a film, and heating the film.

The cured film according to the present invention is manufactured by the above-described method.

The display device according to the present invention comprises the above-described cured film.

### Effects of the Invention

According to the present invention, one or more of the following effects can be desired: the bending performance of the cured film is sufficient; the sensitivity is sufficient; the resolution of the formed pattern is sufficient; the heat resistance of the cured film is sufficient; scum on the cured film can be suppressed; the flatness of the cured film is sufficient; the process window is sufficient; and the manufacturing yield is improved.

### DETAILED DESCRIPTION OF THE INVENTION

### Mode for Carrying Out the Invention

### Definitions

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (II) or another component.

Aryl refers to a group containing one or more aromatic rings and includes phenyl, anthracenyl, naphthyl, phenanthrenyl, fluorenyl, pyrenyl and the like, but is not limited to these.

Aralkyl refers to alkyl substituted with aryl and includes benzyl and phenylethyl and the like, but is not limited to these.

Hereinafter, embodiments of the present invention are described in detail.

### (I) Polysiloxane Material

The present invention relates to a polysiloxane material (I) (hereinafter sometimes referred also to as the component (I), and the same applies also to the other components), which is
a polysiloxane (Pab) comprising a repeating unit represented by the formula (ia) and a repeating unit represented by the formula (ib), or
a mixture of a polysiloxane (Pa) comprising the repeating unit represented by the formula (ia) and a polysiloxane (Pb) comprising the repeating unit represented by the formula (ib).

In the present invention, polysiloxane refers to a polymer having Si—O—Si bonds (siloxane bonds) as its main chain. Further, in the present specification, the general polysiloxane also includes a silsesquioxane polymer represented by the formula (RSiO_{1.5})ₙ.

It can be thought that since the polysiloxane material further polymerizes and becomes the main skeleton of the cured film after the polysiloxane material forms a film, the effects of the present invention are exhibited regardless of whether the repeating unit represented by the formula (ia) and the repeating unit represented by the formula (ib) are both contained in one polymer or the repeating unit represented by the formula (ia) and the repeating unit represented by the formula (ib) are contained in different polymers respectively in a mixture.

Although not to be bound by theory, it can be thought that in the cured film to be formed has appropriate hardness when the repeating unit represented by the formula (ia) is a rigid skeleton like SiO₂ and that the cured film to be formed has appropriate flexibility when the repeating unit represented by the formula (ib) has an organic chain and has a soft structure.

The formula (ia) is as follows:

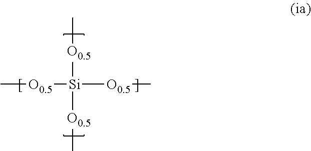

The number of the repeating units represented by the formula (ia) is preferably 1 to 20%, more preferably 1 to 10%, based on the total number of the repeating units contained in the component (I).

The formula (ib) is as follows:

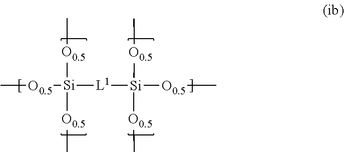

where
L¹ is C₄₋₁₂ linear alkylene;
one or more H in L¹ can be replaced with C₁₋₁₀ linear alkyl, C₃₋₁₀ branched alkyl, C₃₋₁₅ alkyl containing an alicyclic ring, C₆₋₁₅ aryl, —COOH or —OH, preferably not replaced;
one or more non-adjacent methylene (—CH₂—) in L¹ can be replaced with -Ph-, —O—, —S—, —CO—, —CO—O—, —O—CO—, —O—CO—O—, —CR¹═CR²— or —C≡C—, preferably not replaced;
L¹ is preferably C₄₋₁₂ linear alkylene (where H and the methylene in L¹ are not replaced), more preferably linear butylene, hexylene or octylene; and
R¹ and R² are each independently H or C₁₋₆ linear alkyl, preferably H or methyl.

Examples of the formula (ib) are as follows:

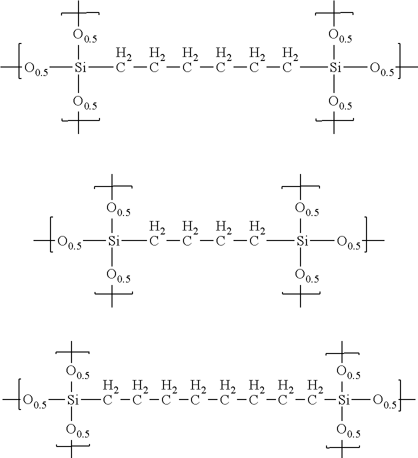

The number of the repeating units represented by the formula (ib) is preferably 1 to 30%, more preferably 1 to 15%, based on the total number of the repeating units contained in the component (I).

Preferably, the component (I) further comprises a repeating unit represented by the formula (ib′).

More preferably, each of the polysiloxane (Pb) further comprises the repeating unit represented by the formula (ib′).

Although not to be bound by theory, further inclusion of the repeating unit represented by formula (ib′) can prevent scum generation, suppress heat flow, increase resolution, and improve sensitivity while maintaining flexibility.

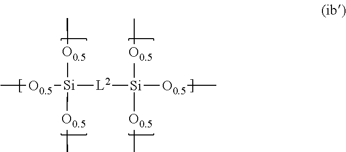

where
L² is C₁₋₃ linear alkylene;
one or more H in L² can be replaced with C₁₋₁₀ linear alkyl, C₃₋₁₀ branched alkyl, C₃₋₁₅ alkyl containing an alicyclic ring, C₆₋₁₅ aryl, —COOH or —OH, preferably not replaced;
one or more non-adjacent methylene (—CH₂—) in L² can be replaced with —O—, —S—, —CO—, —CO—O—, —O—CO—, —O—CO—O—, —CR³═CR⁴— or —C≡C—, preferably not replaced;
R³ and R⁴ are each independently H or C₁₋₆ linear alkyl, preferably H or methyl; and
L² is preferably methylene, ethylene or n-propylene, more preferably methylene or ethylene.

Examples of the formula (ib′) are as follows:

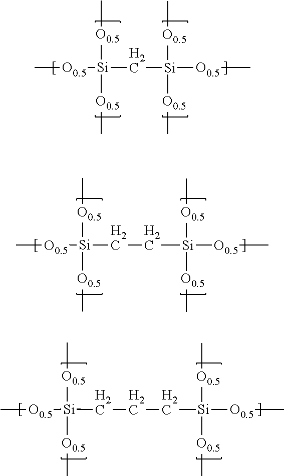

The number of the repeating units represented by the formula (ib′) is preferably 1 to 20%, more preferably 1 to 15%, further preferably 1 to 9%, based on the total number of the repeating units contained in the component (1).

Preferably, the component (I) further comprises a repeating unit represented by the formula (ic).

More preferably, the polysiloxane (Pab), the polysiloxane (Pa) and the polysiloxane (Pb) respectively further comprise the repeating unit represented by the formula (ic):

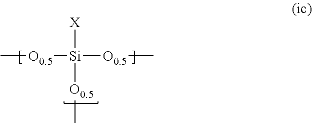

where
X is H, C₁₋₁₀ linear alkyl, C₃₋₁₀ branched alkyl, C₃₋₁₅ alkyl containing an alicyclic ring, C₆₋₁₅ aryl, —COOH or —OH, preferably C₁₋₁₀ linear alkyl or C₆₋₁₅ aryl;
one or more non-adjacent methylene (—CH₂—) in X can be replaced with —O—, —S—, —CO—, —CO—O—, —O—CO—, —O—CO—O—, —CR⁵═CR⁶— or —C≡C—, preferably not replaced; and
R⁵ and R⁶ are each independently H or C₁₋₆ linear alkyl, preferably H or methyl.

Examples of X include alkyl such as methyl, ethyl, propyl, butyl, pentyl, hexyl, heptyl, octyl and decyl; aryl such as phenyl, tolyl and benzyl; cycloalkyl such as cyclohexyl, and preferably methyl, ethyl, propyl, butyl, pentyl, hexyl, phenyl and tolyl. Although not to be bound by theory, a compound in which X is methyl is preferable because the cured film has high hardness and high chemical resistance. Further, although not to be bound by theory, phenyl is preferable because it increases the solubility of the polysiloxane in a solvent and makes the cured film less likely to crack.

The number of the repeating units represented by the formula (ic) is preferably 70 to 99%, more preferably 80 to 95%, further preferably 85 to 90%, based on the total number of the repeating units contained in the component (I).

The component (I) is preferably a mixture of the polysiloxane (Pa) comprising the repeating unit represented by the formula (ia) and the polysiloxane (Pb) comprising the repeating unit represented by the formula (ib).

The number of the repeating units represented by the formula (ia) in the polysiloxane (Pa) is preferably 1% or more, more preferably 3 to 20%, further preferably 5 to 15%, based on the number of all the repeating units contained in the polysiloxane (Pa).

The polysiloxane (Pa) preferably further comprises the repeating unit represented by formula (ic). The number of the repeating units represented by the formula (ic) in the polysiloxane (Pa) is preferably 80 to 97%, more preferably 85 to 95%, based on the number of all the repeating units contained in the polysiloxane (Pa).

The content of the polysiloxane (Pa) is preferably 10 mass % or more, more preferably 30 to 90 mass %, further preferably 40 to 80 mass %, further more preferably 50 to 70 mass %, based on the total mass of the polysiloxane material (1).

The number of the repeating units represented by the formula (ib) in the polysiloxane (Pb) is preferably 1% or more, more preferably 5 to 30%, further preferably 7 to 20%, based on the number of all the repeating units contained in the polysiloxane (Pb).

The polysiloxane (Pb) preferably further comprises the repeating unit represented by the formula (ib′). The number of the repeating units represented by the formula (ib′) in the polysiloxane (Pb) is preferably 1 to 20%, more preferably 5 to 15%, further preferably 7 to 10%, based on the number of all the repeating units contained in the polysiloxane (Pb).

The number of the repeating units represented by the formula (ic) in the polysiloxane (Pb) is preferably 80 to 98%, more preferably 85 to 95%, based on the number of all the repeating units contained in the polysiloxane (Pb).

The content of the polysiloxane (Pb) is preferably 10 mass % or more, more preferably 10 to 70 mass %, further preferably 20 to 60 mass %, further more preferably 30 to 50 mass %, based on the total mass of the polysiloxane material (1).

The polysiloxane (Pab), (Pa) and (Pb) can also comprise the repeating units other than those described above. The number of the repeating units other than those described above is preferably 20% or less, more preferably 10% or less, based on the total number of the repeating units contained in the polysiloxane (Pab), (Pa) and (Pb), respectively. It is also a preferable embodiment of the present invention that the repeating units other than those described above are not contained.

In the present invention, the ratio of the repeating units can be calculated using known structural analysis means for compounds, for example, based on the peak ratio of a ¹H NMR spectrum.

The polysiloxane used in the present invention preferably has silanol at the end. Here, silanol means a group consisting of Si of polysiloxane and OH bonded to the said Si. That is, silanol is composed by binding —O_{0.5}H with —O_{0.5}— of the above formula. The content of silanol in the polysiloxane varies depending on the synthesis conditions of the polysiloxane such as the compounding ratio of monomers and the type of reaction catalyst. The content of this silanol can be evaluated by quantitative infrared absorption spectrum measurement. The absorption band assigned to silanol (SiOH) appears as an absorption band having a peak in the range of 900±100 cm⁻¹ of the infrared absorption spectrum. The higher the content of silanol is, the higher the intensity of this absorption zone is.

The mass average molecular weight (Mw) of the polysiloxane used in the present invention is preferably 500 to 30,000. The Mw is more preferably 500 to 25,000, further preferably 1,000 to 20,000 from the viewpoint of solubility in organic solvents, coatability to substrates and solubility in alkaline developers. Here, the mass average molecular weight is a mass average molecular weight in terms of polystyrene, and can be measured by the gel permeation chromatography based on polystyrene.

The component (I) can be obtained by hydrolyzing and condensing a suitable silicon compound in the presence of an acidic or basic catalyst as required.

The component (I) can be used in a photosensitive composition, in which case it is necessary that a difference in solubility occurs between exposed and unexposed areas. The coating film in the exposed area when the composition according to the present invention is a positive type composition and the coating film in the unexposed area when the composition according to the present invention is a negative type composition should have above a certain level of solubility in the developer. For example, it can be thought possible to form a pattern by exposure and development if the dissolution rate of the coating film after prebaking in a 2.38% tetramethylammonium hydroxide (hereinafter sometimes referred to as TMAH) aqueous solution (hereinafter sometimes referred to as alkali dissolution rate or ADR, and details thereof are described later) is 50 Å/second or higher. However, since the required solubility varies depending on the film thickness of the cured film to be formed or the development conditions, the polysiloxane should be appropriately selected according to the development conditions. Although it varies depending on the type and the amount of the photoactive agent contained in the composition, for example, if the film thickness is 0.1 to 100 μm (1,000 to 1,000,000 Å) when the composition according to the present invention is a positive type composition, the dissolution rate in the 2.38% TMAH aqueous solution is preferably 50 to 5,000 Å/sec, more preferably 200 to 3,000 Å/sec. when the composition according to the present invention is a negative type, the dissolution rate in the 2.38% TMAH aqueous solution is preferably 50 to 20,000 Å/sec, more preferably 1,000 to 10,000 Å/sec.

### <Polysiloxane Composition>

The polysiloxane composition according to the present invention (hereinafter also simply referred to as “composition”) comprises the above-described polysiloxane material (1) and a solvent (11).

The content of the component (I) is preferably 10 to 50 mass %, more preferably 20 to 40 mass %, based on the total mass of the composition excluding the solvent.

### (II) Solvent

The composition according to the present invention comprises a solvent. The solvent is selected from those that uniformly dissolve or disperse each component contained in the composition. In particular, the solvent includes, for example, ethylene glycol monoalkyl ethers, such as ethylene glycol monomethyl ether, ethylene glycol monoethyl ether, ethylene glycol monopropyl ether and ethylene glycol monobutyl ether; diethylene glycol dialkyl ethers, such as diethylene glycol dimethyl ether, diethylene glycol diethyl ether, diethylene glycol dipropyl ether and diethylene glycol dibutyl ether; ethylene glycol alkyl ether acetates, such as methyl cellosolve acetate and ethyl cellosolve acetate; propylene glycol monoalkyl ethers, such as propylene glycol monomethyl ether (PGME) and propylene glycol monoethyl ether; propylene glycol alkyl ether acetates, such as propylene glycol monomethyl ether acetate (PGMEA), propylene glycol monoethyl ether acetate and propylene glycol monopropyl ether acetate; aromatic hydrocarbons, such as benzene, toluene and xylene; ketones, such as methyl ethyl ketone, acetone, methyl amyl ketone, methyl isobutyl ketone and cyclohexanone; alcohols, such as ethanol, propanol, butanol, hexanol, cyclohexanol, ethylene glycol and glycerin; esters, such as ethyl lactate, ethyl 3-ethoxypropionate and methyl 3-methoxypropionate; cyclic esters, such as γ-butyrolactone; and the like. Preferably the solvent is PGMEA, PGME or γ-butyrolactone. These solvents can be used alone or in combination of any two or more.

The compounding ratio of the solvent (II) varies depending on the coating method and the film thickness required after coating. For example, when the composition according to the present invention is applied by spray coating, the compounding ratio can be 90 mass % or more based on the total mass of the composition. However, in slit coating for large glass substrates used in display manufacturing, the compound ratio is usually 50 mass % or more, preferably 60 mass % or more, usually 90 mass % or less, preferably 85 mass % or less.

### (III) Photoactive Agent

The composition according to the present invention may be a non-photosensitive composition or a photosensitive composition. When the composition according to the present invention is a photosensitive composition, the composition according to the present invention further comprises a photoactive agent (III). Photosensitive compositions are classified as positive type photosensitive compositions or negative type photosensitive compositions. In the present invention, the positive type photosensitive composition means a composition that can form a positive image by the steps of applying the composition to form a coating film, exposing the coating film to light so that the solubility of the exposed areas in an alkaline developer increases, and removing the exposed areas by development. The negative type photosensitive composition is a composition that can form a negative image by the steps of applying the composition to form a coating film, exposing the coating film to light so that makes the exposed areas insoluble in an alkaline developer, and removing the unexposed areas by development. In the present invention, a compound that changes in this manner the solubility of the exposed or unexposed areas of the coating film of the polysiloxane composition is referred to as a photoactive agent. In the negative type photosensitive compositions, the solubility of the exposed or unexposed areas may be changed by heat treatment after exposure. In the present invention, for convenience, compounds having such a function are collectively referred to as photoactive agents.

When the composition according to the present invention is a positive type photosensitive composition, a compound that increases the solubility of the exposed areas of the coating film upon irradiation with light is used as a photoactive agent. Such a compound is well known in the field of resist materials, and can also be called, for example, a dissolution inhibitor.

When the composition according to the present invention is a positive type photosensitive composition, the composition preferably comprises a diazonaphthoquinone derivative as a photoactive agent. The composition comprising a diazonaphthoquinone derivative can form a positive image by removing exposed areas by development following making the exposed areas soluble in an alkaline developer. This is because when exposed to light, the exposed area increases its solubility in an alkaline developer due to the generated indenecarboxylic acid while the unexposed area decreases solubility due to interaction with the silanol groups remaining in the polysiloxane.

A preferable diazonaphthoquinone derivative is a compound in which naphthoquinonediazide sulfonic acid is ester-bonded with a compound having a phenolic hydroxyl group. Although there are no particular restrictions on its structure, the diazonaphthoquinone derivative is preferably a compound ester-bonded with a compound having one or more phenolic hydroxy groups. As the naphthoquinonediazide sulfonic acid, 4-naphthoquinonediazide sulfonic acid or 5-naphthoquinonediazide sulfonic acid can be used. The 4-naphthoquinonediazide sulfonic acid ester compound has absorption in the i-line (wavelength: 365 nm) region and is therefore suitable for i-line exposure. Furthermore, the 5-naphthoquinonediazide sulfonic acid ester compound is suitable for exposure over a wide range of wavelength because the said compound has absorption in a wide range of wavelength. It is preferable to select an appropriate diazonaphthoquinone derivative depending on the wavelength to be exposed. It is also possible to use a mixture of the 4-naphthoquinonediazide sulfonic acid ester compound and the 5-naphthoquinonediazide sulfonic acid ester compound.

Although the compound having phenolic hydroxy are not particularly limited, examples of the said compound include bisphenol A, BisP-μF, BisOTBP-A, Bis26B-A, BisP-PR, BisP-LV, BisP-OP, BisP-NO, BisP-DE, BisP-AP, BisOTBP-AP, TrisP-HAP, BisP-DP, TrisP-PA, BisOTBP-Z, BisP-FL, TekP-4HBP, TekP-4HBPA and TrisP-TC (Honshu Chemical Industry Co., Ltd.).

Although the optimum amount of the diazonaphthoquinone derivative to be added varies depending on the esterification rate of naphthoquinonediazide sulfonic acid, the physical properties of the polysiloxane used, the required sensitivity, and the dissolution contrast between exposed and unexposed areas, the compounding amount of the diazonaphthoquinone derivative is preferably 20 parts by mass or less, for example, 1 to 20 parts by mass, more preferably 3 to 15 parts by mass, based on 100 parts by mass of the polysiloxane. When the compounding amount of the diazonaphthoquinone derivative is 1 part by mass or more, the dissolution contrast between exposed area and unexposed area becomes higher, resulting in sufficient photosensitivity. Further, in order to obtain further better dissolution contrast, the amount of the diazonaphthoquinone derivative is preferably 3 parts by mass or more. On the other hand, it is preferable that the compounding amount of the diazonaphthoquinone derivative is smaller in terms of the better colorless transparency of the cured film and the higher transmittance.

When the composition according to the present invention is a negative type photosensitive composition, a compound that reduces the solubility of exposed area of the coating film upon irradiation with light is used as a photoactive agent. Such a compound is generally called a photosensitizer and is selected depending on the type of resist resin used, and includes compounds selected from the group consisting of, for example, photoacid generators, photobase generators, photothermal acid generators and photothermal base generators. The negative type photosensitive composition according to the present invention preferably comprises any one or more of these.

Although the optimum content of the photoactive agent used in the negative type photosensitive composition varies depending on the type of active substance generated by decomposition, the amount generated, the required sensitivity and the dissolution contrast between exposed and unexposed areas, the compounding amount is preferably 20 parts by mass or less, for example 0.1 to 10 parts by mass, more preferably 0.5 to 5 parts by mass, based on 100 parts by mass of the total mass of the polysiloxane. When the compounding amount is less than 0.1 part by mass, the amount of acid or base generated is too small, and polymerization during post-baking is not accelerated, making it easy to cause pattern sagging. On the other hand, if the compounding amount is more than 20 parts by mass, cracks may occur in the cured film to be formed, and coloration due to these decompositions may become noticeable, which may reduce the colorless transparency of the cured film. Further, if the compounding amount is large, thermal decomposition may cause deterioration of the electrical insulation properties of the cured product or gas release, which can cause problems in subsequent steps. Furthermore, the resistance of the cured film to photoresist remover containing monoethanolamine or the like as a main ingredient can be reduced.

In the present invention, the photoacid generator or the photobase generator refers to a compound that generates an acid or base by causing bond cleavage upon exposure. It can be thought that the generated acid or base contributes to the polymerization of the polysiloxane. Here, examples of light include visible light, ultraviolet ray, infrared ray, X-ray, electron beam, α-ray, γ-ray or the like.

The photoacid generator can be optionally selected from commonly used ones, such as diazomethane compounds, triazine compounds, sulfonic acid esters, diphenyliodonium salts, triphenylsulfonium salts, sulfonium salts, ammonium salts, phosphonium salts and sulfonimide compounds.

Exemplified embodiments of the photoacid generator that can be used, including those described above, are 4-methoxyphenyl diphenyl sulfonium hexafluorophosphonate, 4-methoxyphenyl diphenyl sulfonium hexafluoroarsenate, 4-methoxyphenyl diphenyl sulfonium methane sulfonate, 4-methoxyphenyldiphenylsulfonium trifluoroacetate, triphenylsulfonium tetrafluoroborate, triphenylsulfonium tetrakis(pentafluorophenyl)borate, triphenylsulfonium hexafluorophosphonate, triphenylsulfonium hexafluoroarsenate, 4-methoxyphenyl diphenyl sulfonium-p-toluene sulfonate, 4-phenyl thiophenyl diphenyl tetrafluoroborate, 4-phenyl thiophenyl diphenyl hexafluorophosphonate, triphenyl sulfonium methanesulfonate, triphenylsulfonium trifluoroacetate, triphenylsulfonium-p-toluenesulfonate, 4-methoxyphenyl diphenylsulfonium tetrafluoroborate, 4-phenylthiophenyl diphenyl hexafluoroarsenate, 4-phenylthiophenyl diphenyl-p-toluenesulfonate, N-(trifluoromethylsulfonyloxy)succinimide, N-(trifluoromethylsulfonyloxy)phthalimide, 5-norbornene-2,3-dicarboximidyl triflate, 5-norbornene-2,3-dicarboximidyl-p-toluenesulfonate, 4-phenylthiophenyldiphenyltrifluoromethanesulfonate, 4-phenylthiophenyl diphenyl trifluoroacetate, N-(trifluoromethylsulfonyloxy)diphenylmaleimide, N-(trifluoromethylsulfonyloxy)bicyclo[2.2.1]hept-5-ene-2,3-dicarboximide, N-(trifluoromethylsulfonyloxy)naphthylimide, N-(nonafluorobutylsulfonyloxy)naphthylimide, and the like.

In addition, when absorption of h-line is not desired, use of 5-propylsulfonyloxyimino-5H-thiophen-2-ylidene-(2-methylphenyl)acetonitrile, 5-octylsulfonyloxyimino-5H-thiophene-2-ylidene-(2-methylphenyl)-acetonitrile, 5-camphorsulfonyloxyimino-5H-thiophene-2-ylidene-(2-methylphenyl)acetonitrile, 5-methylphenylsulfonyloxyimino-5H-thiophene-2-ylidene-(2-methylphenyl)acetonitrile, and the like should be avoided, since they have absorption in the wavelength region of h-line.

Examples of the photobase generator include multi-substituted amide compounds having an amide group, lactams, imide compounds or those containing the structure thereof.

Further, an ionic photobase generator including an amide anion, a methide anion, a borate anion, a phosphate anion, a sulfonate anion, a carboxylate anion, and the like as an anion can also be used.

In the present invention, the photothermal acid generator or photothermal base generator refers to a compound that changes its chemical structure but does not generate an acid or base upon exposure, and then causes a bond cleavage by heat to generate an acid or base. Among these, photothermal base generator is preferable.

### (IV) Other Additives

In addition to the above-described (I) to (III), the composition according to the present invention can comprise other additives (IV), if necessary. The component (IV) includes, for example, a surfactant, an acid, a base, a thermal acid generator, a thermal base generator, a developer solubility promoter, a scum remover, an adhesion enhancer, a polymerization initiator, an antifoaming agent or a sensitizer, and one or more types therefrom can be selected.

The content of component (IV) is preferably 0 to 0.5 mass %, more preferably 0.01 to 0.1 mass %, based on the total mass of the composition excluding the solvent.

### <Method for Manufacturing Film and Cured Film>

The method for manufacturing a film according to the present invention comprises applying the above-described composition above a substrate, optionally exposing, and developing.

The method for manufacturing a cured film according to the present invention further comprises heating the film.

First, the above-described composition is applied above a substrate. Formation of a coating film of the composition in the present invention can be performed by any method conventionally known as a method for applying a composition. In particular, any method can be selected from dip coating, roll coating, bar coating, brush coating, spray coating, doctor blade coating, flow coating, spin coating, slit coating, and the like.

As the substrate above which the composition is applied, a suitable substrate such as a silicon substrate, a glass substrate or a resin film can be used. Various semiconductor devices and the like may be formed above these substrates as necessary. If the substrate is a film, gravure coating can also be used. If desired, a drying step can be separately provided after coating. Moreover, the coating step can be repeated once or twice or more as necessary to obtain a desired film thickness of the coating film formed.

After forming a coating film of the composition according to the present invention, it is preferable to subject to prebaking (heat treating) the coating film in order to dry the coating film and reduce the amount of residual solvent. The prebaking step can be generally carried out at a temperature of 70 to 150° C., preferably 90 to 120° C., for 10 to 180 seconds, preferably 30 to 90 seconds when using a hot plate, and for 1 to 30 minutes when using a clean oven.

When the composition according to the present invention is a non-photosensitive composition, the coating film is then cured by heating. The heating temperature in this heating step is not particularly limited so long as it is a temperature at which the coating film can be cured, and can be optionally determined. However, if silanol groups remain, the chemical resistance of the cured film can become insufficient or the dielectric constant of the cured film can become high. From this point of view, a relatively high heating temperature is generally selected. In order to accelerate the curing reaction and obtain a sufficiently cured film, the curing temperature is preferably 200° C. or higher. Further, although the heating time is not particularly limited, the heating time is generally 10 minutes to 24 hours, preferably 20 minutes to 3 hours. In addition, this heating time is the time after the temperature of the patterned film reaches the desired heating temperature. Usually, it takes several minutes to several hours for the patterned film to reach the desired temperature from the temperature before heating.

When the composition according to the present invention is a photosensitive composition, the surface of the coating film is then irradiated with light. As the light source used for light irradiation, any light source conventionally used in pattern forming methods can be used. Examples of such light sources include high-pressure mercury lamp, low-pressure mercury lamp, metal halide lamp, xenon lamp, laser diode, LED, and the like. As the irradiation light, ultraviolet rays such as g-line, h-line, and i-line are usually used. Except for ultra-fine processing of semiconductors, it is common to use light of 360 to 430 nm (high-pressure mercury lamp) for patterning from several μm to several tens of μm. Among these, 430 nm light is often used in the case of liquid crystal display devices. The irradiation light energy depends on the light source and the film thickness of the coating film, but is generally 5 to 2,000 mJ/cm², preferably 10 to 1,000 mJ/cm². If the irradiation light energy is lower than 5 mJ/cm², sufficient resolution may not be obtained; on the other hand, if the irradiation light energy is higher than 2,000 mJ/cm², overexposure may occur, thereby leading to the occurrence of halation.

A general photomask can be used to irradiate light in a pattern. Such a photomask can be optionally selected from known ones. The environment during irradiation is not particularly limited, but may generally be an ambient atmosphere (in the atmosphere) or a nitrogen atmosphere. Furthermore, in the case of forming a cured film on the entire surface of the substrate, the entire surface of the substrate may be irradiated with light. In the present invention, the term “patterned film” includes a case where a cured film is formed over the entire surface of the substrate.

After exposure, in order to promote the reaction between polymers each other in the coating film by the acid or base generated in exposed area, post-exposure baking can be performed as necessary, especially when the composition according to the present invention is a negative type. Unlike the heating step to be described below, this heat treatment is not performed to completely cure the coating film, but this is done in such a way that only the desired pattern remains on the substrate after development and it becomes possible to remove the other portion by development.

When the post exposure baking is performed, a hot plate, oven, furnace, etc. can be used. The heating temperature should not be set too high because it is undesirable for the acid or base generated in exposed area by light irradiation to diffuse into unexposed area. From this point of view, the heating temperature range after exposure is preferably 40° C. to 150° C., more preferably 60° C. to 120° C. Stepwise heating can also be applied, if desired, to control the curing rate of the composition. The atmosphere during heating is not particularly limited, but can be selected from in inert gas such as nitrogen, or vacuum, reduced pressure, in oxygen gas, etc. for the purpose of controlling the curing rate of the composition. Further, the heating time is preferably above a certain level in order to maintain higher uniformity of the temperature history within the wafer surface, and is preferably not excessively long in order to suppress the diffusion of the generated acid. From this point of view, the heating time is preferably 20 seconds to 500 seconds, more preferably 40 seconds to 300 seconds.

It is preferable not to perform the post exposure baking step when using a positive type photosensitive composition in order not to promote crosslinking between polymer each other.

After exposure, the coating film is subjected to development treatment. As the developer used during development, any developer conventionally used for developing photosensitive compositions can be used. Preferable developers include alkaline developers that are aqueous solutions of alkaline compounds, such as tetraalkylammonium hydroxide, choline, alkali metal hydroxide, alkali metal metasilicate (hydrate), alkali metal phosphate (hydrate), ammonia water, alkylamine, alkanolamine and heterocyclic amines, and a particularly preferable alkaline developer is an aqueous solution of tetramethylammonium hydroxide. In these alkaline developers, a water-soluble organic solvent such as methanol or ethanol, or a surfactant can be further comprised, if necessary. The developing method can also be optionally selected from conventionally known methods. In particular, the methods include immersion (dipping) in a developer, paddle, shower, slit, cap coat, and spray. By this development, a pattern can be obtained. After development is performed with a developer, it is preferable to perform water washing.

Thereafter, a full-surface exposure (flood exposure) step is normally performed. When using a photoacid generator or a photobase generator, an acid or a base is generated in this flood exposure step. When a photothermal acid generator or a photothermal base generator is used, the chemical structure of the photothermal acid generator or the photothermal base generator changes in this flood exposure step. Further, if unreacted diazonaphthoquinone derivative remaining in the coating film is present, it is photodegraded, and the optical transparency of the cured film is further improved. Therefore, if transparency is desired, it is preferable to perform a flood exposure step. Even when a thermal acid generator or a thermal base generator is added when the composition according to the present invention is a positive type, it is preferable to perform flood exposure for the above purpose. The method for performing the flood exposure include a method in which using a UV-visible exposure machine such as an aligner (for example, Canon Inc., PLA-501F) and exposing the full-surface to approximately 100 to 2,000 mJ/cm² (converted to the exposure amount at a wavelength of 365 nm).

Curing the coating film is conducted by heating the obtained pattern film. The heating conditions are the same as when using the above-described non-photosensitive composition.

The Young's modulus of the cured film obtained can be measured by a method such as nanoindentation. Nanoindentation is a method that simultaneously measures load and displacement by pushing an indenter into a desired location on a measurement sample. From the load-displacement curve at this time, the hardness and Young's modulus (elastic modulus) of the measurement sample can be obtained. Measuring machines include the ENT series (Elionix) and the like.

The cured film that is formed has a Young's modulus of 3.4 GPa or less, more preferably 3.0 GPa or less.

The cured film thus formed can be suitably used in a variety of fields as an interlayer insulating film for various devices, a transparent protective film, and also as an interlayer insulating film for low-temperature polysilicon, a buffer coat film for IC chips, etc.

The cured film formed is then subjected to further post-processing such as processing and circuit formation on the substrate as necessary to form a device, preferably a display device. Any conventionally known method can be applied to these post-processing.

### Example

The present invention is described below with reference to various examples. In addition, the embodiments of the present invention are not limited only to these examples.

The mass average molecular weight (Mw) is measured by the gel permeation chromatography (GPC) based on polystyrene. GPC is measured using an Alliance™ e2695 type high-speed GPC system (Nihon Waters K.K.) and a Super Multipore HZ-N type GPC column (Tosoh Corporation). After the measurement is carried out using monodisperse polystyrene as a standard sample and tetrahydrofuran as a developing solvent under the measurement conditions of a flow rate of 0.6 ml/min and a column temperature of 40° C., Mw is calculated as the relative molecular weight to the standard sample.

### [Synthesis of Polysiloxane Pa-1]

In a 2 L flask equipped with a stirrer, a thermometer and a condenser, 49.0 g of a 25 mass % aqueous solution of tetramethylammonium hydroxide (TMAH), 470 g of isopropyl alcohol (IPA) and 4.0 g of water are charged, and then in a dropping funnel, a mixed solution of 68.0 g of methyltrimethoxysilane, 79.2 g of phenyltrimethoxysilane and 15.2 g of tetramethoxysilane is prepared. The mixed solution is added dropwise at 40° C., stirred at the same temperature for 2 hours, and then neutralized by adding a 10% aqueous solution of HCl. 400 ml of toluene and 600 ml of water are added to the neutralized liquid to separate into two phases, and the aqueous phase is removed. Further, the organic phase is washed three times with 300 ml of water, the solvent is removed by concentrating the obtained organic phase under reduced pressure, and PGMEA is added to the concentrate to adjust the solid content concentration to 35 mass %.

The Mw of the obtained Polysiloxane Pa-1 is 1,800. The obtained resin solution is applied on a silicon wafer using a spin coater (MS-A100 (Mikasa Corporation)) so that the film thickness after prebaking becomes 2 μm. After prebaking, the dissolution rate (ADR) in a 2.38% TMAH aqueous solution is measured. The measured ADR is 1,200 Å/sec.

### [Synthesis of Polysiloxane Pb-1]

In a 300 mL flask equipped with a stirrer, a thermometer and a condenser, 26.03 g of a 25 mass % aqueous solution of TMAH and 40 g of PGME are charged, and then in a dropping funnel, a mixed solution of 13.6 g of methyltrimethoxysilane, 15.84 g of phenyltrimethoxysilane and 14.18 g of 1,2-bis(trimethoxysilyl)ethane is prepared. The mixed solution is added dropwise at 5° C., stirred at 25° C. for 2 hours, and then neutralized by adding 29.63 g of a PGME solution containing 28 mass % maleic acid. 100 g of normal propyl acetate (nPA) and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 45 mass %.

The obtained Polysiloxane Pb-1 has a Mw of 7,790 and an ADR of 4,850 Å/sec.

### [Synthesis of Polysiloxane Pb-2]

In a 300 mL flask equipped with a stirrer, a thermometer and a condenser, 27.23 g of a 25 mass % aqueous solution of TMAH, and 40 g of PGME are charged, and then in a dropping funnel, a mixed solution of 8.16 g of methyltrimethoxysilane, 23.76 g of phenyltrimethoxysilane and 14.18 g of 1,2-bis(trimethoxysilyl)ethane is prepared. The mixed solution is added dropwise at 5° C., stirred at 25° C. for 2 hours, and then neutralized by adding 31.02 g of a PGME solution containing 28 mass % maleic acid. 180 g of ethyl acetate and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 40 mass %.

The obtained Polysiloxane Pb-2 has a Mw of 5,120 and an ADR of 2,640 Å/sec.

### [Synthesis of Polysiloxane Pb-3]

In a 300 mL flask equipped with a stirrer, a thermometer and a condenser, 28.03 g of a 25 mass % aqueous solution of TMAH and 40 g of PGME are charged, and then in a dropping funnel, a mixed solution of 13.6 g of methyltrimethoxysilane, 15.84 g of phenyltrimethoxysilane and 13.06 g of 1,6-bis(trimethoxysilyl)hexane is prepared. The mixed solution is added dropwise at 5° C., stirred at 25° C. for 2 hours, and then neutralized by adding 31.92 g of a PGME solution containing 28 mass % maleic acid. 100 g of nPA and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 35 mass %.

The obtained Polysiloxane Pb-3 has a Mw of 6,450 and an ADR of 6,860 Å/sec.

### [Synthesis of Polysiloxane Pb-4]

In a 300 mL flask equipped with a stirrer, a thermometer and a condenser, 36.04 g of a 25 mass % aqueous solution of TMAH and 40 g of PGME are charged, and then in a dropping funnel, a mixed solution of 13.6 g of methyltrimethoxysilane, 15.84 g of phenyltrimethoxysilane and 17.55 g of 1,8-bis(triethoxysilyl)octane is prepared. The mixed solution is added dropwise at 5° C., stirred at 25° C. for 2 hours, and then neutralized by adding 41.03 g of a PGME solution containing 28 mass % maleic acid. 140 g of nPA and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 20 mass %.

The obtained Polysiloxane Pb-4 has a Mw of 9,940 and an ADR of 2,440 Å/sec.

### [Synthesis of Polysiloxane Pb-5]

In a 300 mL flask equipped with a stirrer, a thermometer and a condenser, 30.43 g of a 25 mass % aqueous solution of TMAH and 40 g of PGME are charged, and then in a dropping funnel, a mixed solution of 13.6 g of methyltrimethoxysilane, 15.84 g of phenyltrimethoxysilane, 7.09 g of 1,2-bis(trimethoxysilyl)ethane and 6.53 g of 1,6-bis(trimethoxysilyl)hexane is prepared. The mixed solution is added dropwise at 5° C., stirred at 25° C. for 2 hours, and then neutralized by adding 34.67 g of a PGME solution containing 28 mass % maleic acid. 140 g of nPA and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 40 mass %.

The obtained Polysiloxane Pb-5 has a Mw of 7,840 and an ADR of 3,360 Å/sec.

### [Synthesis of Polysiloxane Pb-6]

In a 300 mL flask equipped with a stirrer, a thermometer and a condenser, 29.63 g of a 25 mass % aqueous solution of TMAH and 40 g of PGME are charged, and then in a dropping funnel, a mixed solution of 13.6 g of methyltrimethoxysilane, 15.84 g of phenyltrimethoxysilane, 7.09 g of 1,2-bis(trimethoxysilyl)ethane and 8.78 g of 1,8-bis(triethoxysilyl)octane is prepared. The mixed solution is added dropwise at 5° C., stirred at 25° C. for 2 hours, and then neutralized by adding 33.74 g of a PGME solution containing 28 mass % maleic acid. 140 g of nPA and 60 g of water are added to the neutralized liquid to separate into two phases, and the aqueous phase is removed. Further, the organic phase is washed three times with 60 g of water, the solvent is removed by concentrating the obtained organic phase under reduced pressure, and PGMEA is added to the concentrate to adjust the solid content concentration to 40 mass %.

The obtained Polysiloxane Pb-6 has a Mw of 8,250 and an ADR of 2,420 Å/sec.

The ratios of the numbers of the repeating units of the polysiloxane synthesized above are summarized in Table 1. In Table 1, (ia), (ib), (ib′) and (ic) mean the repeating units represented by the formula (ia), the formula (ib), the formula (ib′) and the formula (ic), respectively.

TABLE 1

| | | (ib) | | (ib′) | (ic) | |
|---|---|---|---|---|---|---|
| | | L¹ = | L¹ = | L² = | X = | X = |
| | (ia) | C₆H₁₂ | C₈H₁₄ | C₂H₄ | methyl | phenyl |
| Polysiloxane Pa-1 | 10 | — | — | — | 50 | 40 |
| Polysiloxane Pb-1 | — | — | — | 18.1 | 45.5 | 36.4 |
| Polysiloxane Pb-2 | — | — | — | 18.2 | 27.3 | 54.5 |
| Polysiloxane Pb-3 | — | 18.1 | — | — | 45.5 | 36.4 |
| Polysiloxane Pb-4 | — | — | 18.1 | — | 45.5 | 36.4 |
| Polysiloxane Pb-5 | — | — | 9.05 | 9.05 | 45.5 | 36.4 |
| Polysiloxane Pb-6 | — | 9.05 | — | 9.05 | 45.5 | 36.4 |

### Example 1

28.256 parts by mass of polysiloxane in which the mass ratio of Polysiloxane Pa-1 and Polysiloxane Pb-5 is 50:50, 1.695 parts by mass of diazonaphthoquinone derivative “TPPA-280 Å” (Toyo Gosei Co., Ltd.), 0.028 parts by mass of a surfactant “AKS-10” (Shin-Etsu Chemical Co., Ltd.) and 0.02 parts by mass of maleic acid are dissolved in a mixed solvent of 36.75 parts by mass of PGMEA, 26.25 parts by mass of PGME and 7 parts by mass of γ-butyrolactone to obtain the composition of Example 1.

### Examples 2 to 5 and Comparative Examples 1 to 7

The compositions of Examples 2 to 5 and Comparative Examples 1 to 7 are prepared in the same manner as described in Example 1, except that the type of polysiloxane and the mixing ratio (based on mass) are changed as shown in Table 2.

TABLE 2

| | Example | | | | | Comparative Example | | | | | | |
|---|---|---|---|---|---|---|---|---|---|---|---|---|
| | 1 | 2 | 3 | 4 | 5 | 1 | 2 | 3 | 4 | 5 | 6 | 7 |
| Polysiloxane Pa-1 | 50 | 50 | 50 | 50 | 70 | 50 | 40 | 50 | 100 | — | — | — |
| Polysiloxane Pb-1 | — | — | — | — | — | 50 | 60 | — | — | 100 | — | — |
| Polysiloxane Pb-2 | — | — | — | — | — | — | — | 50 | — | — | — | — |
| Polysiloxane Pb-3 | — | — | 50 | — | — | — | — | — | — | — | 100 | — |
| Polysiloxane Pb-4 | — | — | — | 50 | 30 | — | — | — | — | — | — | 100 |
| Polysiloxane Pb-5 | 50 | — | — | — | — | — | — | — | — | — | — | — |
| Polysiloxane Pb-6 | — | 50 | — | — | — | — | — | — | — | — | — | — |
| Exposure amount (E) | 60 | 50 | 80 | 110 | 110 | 90 | 60 | 150 | — | — | — | — |
| [mJ/cm²] | | | | | | | | | | | | |
| Sensitivity Evaluation | A | A | B | B | B | B | A | C | — | — | — | — |
| Pattern size after | 4.94 | 4.96 | 5.48 | 5.01 | 4.75 | 5.06 | 5.2 | 5.06 | — | — | — | — |
| curing | | | | | | | | | | | | |
| [μm] | | | | | | | | | | | | |
| Bending performance | A | A | A | A | A | C | C | B | C | C | C | C |
| evaluation | | | | | | | | | | | | |

### [Sensitivity Evaluation]

The compositions of Examples 1 to 5 and Comparative Examples 1 to 3 are applied by spin coating on a 4-inch silicon wafer subjected to HMDS treatment so that the final film thickness becomes 1.5 μm respectively. The resulting coating films are prebaked at 100° C. for 90 seconds to evaporate the solvent respectively. The dried coating films are pattern-exposed using a g+h+i-line stepper (NES2W-ghi06, Nikon Corporation) at varying exposure amount from 50 mJ/cm² to 200 mJ/cm² using contact holes containing 5 μm holes and 15 μm spaces respectively. After exposure, paddle development is performed for 70 seconds using a 2.38% TMAH aqueous solution respectively, and the pattern is further rinsed with pure water for 60 seconds to dry the pattern respectively. The dried patterns are subjected to flood exposure at 1,000 mJ/cm² using a g+h+i-line mask aligner (PLA-501F model, Canon Inc.), and are further heated in the atmosphere at 250° C. for 60 minutes, thereby curing respectively. The hole diameter size of the patterns after curing are measured using a scanning electron microscope (SEM), and holes having a hole diameter of 5±0.5 μm are identified respectively. The exposure amount (E) at the time of pattern exposure to the identified holes are confirmed respectively, and E and the pattern sizes after curing at that time are shown in Table 2.

The coating films are evaluated as “A” when E is less than 70 mJ/cm², “B” when E is 70 mJ/cm² or more and less than 150 mJ/cm², and “C” when E is 150 mJ/cm² or more, and the results are shown in Table 2.

### [Bending Performance Evaluation]

A 7 cm square polyimide (PI) films with a thickness of 15 μm is fixed on 4-inch silicon wafers with Kapton tape, and the compositions of Examples 1 to 5 and Comparative Examples 1 to 7 are applied by spin coating so as to become a final film thickness of 2 μm respectively. The resulting coating films are prebaked at 120° C. for 90 seconds to evaporate the solvent. The dried coating films are not exposed to light, but are subjected to paddle development using a 2.38% TMAH aqueous solution for 70 seconds, further rinsed with pure water for 60 seconds, and dried respectively. The dried coating films are subjected to flood exposure at 1,000 mJ/cm² using a g+h+i-line mask aligner (PLA-501F model, Canon Inc.), and further heated in the atmosphere at 230° C. for 30 minutes to form cured films respectively. The PI films on which the cured films are attached are peeled off from the silicon wafers, and the PI films are bended along the piano wires placed on the back side respectively. Creases are made with the thumb from the surface side of the PI films, and then the surface of the cured films of the opened PI films are observed with an optical microscope respectively. The thickness of the piano wires is changed in the order of 1.0 mm, 0.5 mm, 0.3 mm, 0.2 mm and 0.1 mm respectively. Depending on the degree of scratch to the cured film, the cured films are divided into following levels:
Level 0: no scratches are confirmed
Level 1: fine line scratches are slightly confirmed
Level 2: thick line scratches are slightly confirmed
Level 3: many scratches are confirmed, or the cured film is peeled off and evaluated according to the following criteria:
A: all piano wires are level 0
B: the thickness of the piano wire when the evaluation reaches level 1, 2, or 3 for the first time is 0.2 mm or 0.1 mm
C: the thickness of the piano wire when the evaluation reaches level 1, 2, or 3 for the first time is 1.0 mm, 0.5 mm or 0.3 mm

The results obtained are shown in Table 2.

### [Pattern Hardness: Young's Modulus]

29.9 parts by mass of Polysiloxane Pb-1, Polysiloxane Pb-3 and Polysiloxane Pb-4 are each respectively dissolved in a mixed liquid composed of 0.1 parts by mass of a surfactant “AKS-10” (Shin-Etsu Chemical Co., Ltd.) and 70 parts by mass of PGME, to prepare the compositions Pb-1, Pb-3 and Pb-4. Using these compositions and the composition of Comparative Example 1, cured films are formed in the same manner as in the above-described bending performance evaluation, and the hardness of the cured films are measured using a nanoindenter (ENT-2100, Elionix INC.) respectively. The test load is set to be 0.15 mN. The results obtained are 3.5 GPa for the composition of Comparative Example 1; 3.4 GPa for the composition Pb-1; 2.1 GPa for the composition Pb-3; and 2.0 GPa for the composition Pb-4. Although not to be bound by theory, it is presumed from this result that the repeating unit represented by the formula (ia) imparts appropriate hardness to the cured film, and the repeating unit represented by the formula (ib) imparts appropriate flexibility to the cured film.

1. A polysiloxane material (I), which is
a polysiloxane (Pab) comprising a repeating unit represented by the formula (ia) and a repeating unit represented by the formula (ib), or
a mixture of a polysiloxane (Pa) comprising the repeating unit represented by the formula (ia) and a polysiloxane (Pb) comprising the repeating unit represented by the formula (ib): 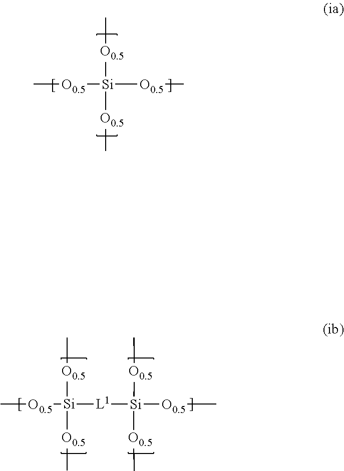
where
L¹ is C₄₋₁₂ linear alkylene;
one or more H in L¹ can be replaced with C₁₋₁₀ linear alkyl, C₃₋₁₀ branched alkyl, C₃₋₁₅ alkyl containing an alicyclic ring, C₆₋₁₅ aryl, —COOH or —OH;
one or more non-adjacent methylene (—CH₂—) in L¹ can be replaced with -Ph-, —O—, —S—, —CO—, —CO—O—, —O—CO—, —O—CO—O—, —CR¹═CR²— or —C≡C—; and
R¹ and R² are each independently H or C₁₋₆ linear alkyl.

2. The polysiloxane material (I) according to claim 1, wherein L¹ is C₄₋₁₂ linear alkylene (where H and methylene in L¹ are not replaced).

3. The polysiloxane material (I) according to claim 1, wherein the polysiloxane (Pab), the polysiloxane (Pa) and the polysiloxane (Pb) further comprise a repeating unit represented by the formula (ic): 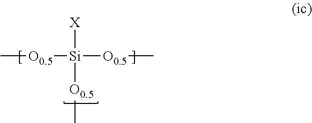
where
X is H, C₁₋₁₀ linear alkyl, C₃₋₁₀ branched alkyl, C₃₋₁₅ alkyl containing an alicyclic ring, C₆₋₁₅ aryl, —COOH or —OH;
one or more non-adjacent methylene (—CH₂—) in X can be replaced with —O—, —S—, —CO—, —CO—O—, —O—CO—, —O—CO—O—, —CR⁵═CR⁶— or —C≡C—; and
R⁵ and R⁶ are each independently H or C₁₋₆ linear alkyl.

4. The polysiloxane material (I) according to claim 3, wherein X is C₁₋₁₀ linear alkyl or C₆₋₁₅ aryl.

5. The polysiloxane material (I) according to claim 1, which is a mixture of the polysiloxane (Pa) comprising the repeating unit represented by the formula (ia) and the polysiloxane (Pb) comprising the repeating unit represented by the formula (ib).

6. The polysiloxane material (I) according to claim 5, wherein the content of the polysiloxane (Pb) is 10 mass % or more based on the total mass of the polysiloxane material (I).

7. The polysiloxane material (I) according to claim 5, wherein the number of the repeating units represented by the formula (ib) in the polysiloxane (Pb) is 5% or more based on the number of all the repeating units contained in the polysiloxane (Pb).

8. The polysiloxane material (I) according to claim 5, wherein the polysiloxane (Pb) further comprises a repeating unit represented by the formula (ib′): 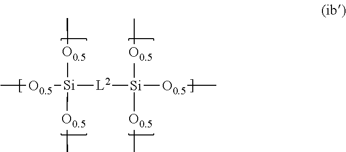
where
L² is C₁₋₃ linear alkylene;
one or more H in L² can be replaced with C₁₋₁₀ linear alkyl, C₃₋₁₀ branched alkyl, C₃₋₁₅ alkyl containing an alicyclic ring, C₆₋₁₅ aryl, —COOH or —OH;
one or more non-adjacent methylene (—CH₂—) in L² can be replaced with —O—, —S—, —CO—, —CO—O—, —O—CO—, —O—CO—O—, —CR³═CR⁴— or —C≡C—; and
R³ and R⁴ are each independently H or C₁₋₆ linear alkyl.

9. The polysiloxane material (I) according to claim 8, wherein L² is methylene, ethylene or propylene.

10. A polysiloxane composition comprising the polysiloxane material (I) according to claim 1, and a solvent (II).

11. The composition according to claim 10, further comprising a photoactive agent (III).

12. The composition according to claim 10, which is a positive type photosensitive composition.

13. The composition according to claim 10, which is a negative type photosensitive composition.

14. A method for manufacturing a film, comprising applying the composition according to claim 10 above a substrate, optionally exposing, and developing.

15. A method for manufacturing a cured film, comprising manufacturing a film according to claim 14 and heating the film.

16. A cured film manufactured by the method according to claim 15.

17. The cured film according to claim 16, which has a Young's modulus of 3.4 GPa or less.

18. A display device comprising the cured film according to claim 16.

19. The polysiloxane material (I) according to claim 2, wherein the polysiloxane (Pab), the polysiloxane (Pa) and the polysiloxane (Pb) further comprise a repeating unit represented by the formula (ic): 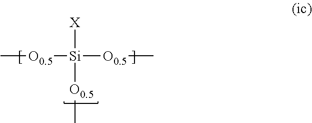
where
X is H, C₁₋₁₀ linear alkyl, C₃₋₁₀ branched alkyl, C₃₋₁₅ alkyl containing an alicyclic ring, C₆₋₁₅ aryl, —COOH or —OH;
one or more non-adjacent methylene (—CH₂—) in X can be replaced with —O—, —S—, —CO—, —CO—O—, —O—CO—, —O—CO—O—, —CR⁵═CR⁶— or —C≡C—; and
R⁵ and R⁶ are each independently H or C₁₋₆ linear alkyl.

20. The polysiloxane material (I) according to claim 19, wherein X is C₁₋₁₀ linear alkyl or C₆₋₁₅ aryl.
